(19) United States
(12) Patent Application Publication
(10) Pub. No.: US 2026/0223414 A1
(43) Pub. Date: Jul. 30, 2026

(54) EPITAXIAL NITRIDE FERROELECTRONIC DEVICES

(71) Applicant: The Regents of the University of Michigan, Ann Arbor, MI (US)

(72) Inventors: Ding Wang, Ann Arbor, MI (US); Ping Wang, Ann Arbor, MI (US); Zetian Mi, Ann Arbor, MI (US); Jiangnan Liu, Ann Arbor, MI (US)

(21) Appl. No.: 19/145,467

(22) PCT Filed: Jan. 8, 2024
(86) PCT No.: PCT/US2024/010730

§ 371 Date: Jul. 2, 2025

Related U.S. Application Data
(60) Provisional application No. 63/437,670, filed on Jan. 7, 2023.

(51) Int. Cl. H10D 30/69; H10D 30/01; H10D 30/47; H10D 62/824; H10D 64/01; H10D 64/68

(52) U.S. Cl. CPC H10D 30/701; H10D 30/015; H10D 30/0413; H10D 30/0415; H10D 30/475; H10D 64/01358; H10D 64/689; H10D 30/69; H10D 62/824

(57) ABSTRACT

A transistor device includes a substrate and a heterostructure supported by the substrate. The heterostructure includes a buffer layer supported by the substrate, a channel layer supported by the buffer layer, a barrier layer supported by the channel layer, and a gate dielectric layer supported by the barrier layer. The gate dielectric layer includes a ferroelectric nitride alloy, the ferroelectric nitride alloy including a Group IIIB element.

### CROSS-REFERENCE TO RELATED APPLICATION

This application claims the benefit of U.S. provisional application entitled “Epitaxial Nitride Ferroelectronic Devices,” filed Jan. 7, 2023, and assigned Ser. No. 63/437,670, the entire disclosure of which is hereby expressly incorporated by reference.

### BACKGROUND OF THE DISCLOSURE

### Field of the Disclosure

The disclosure relates generally to ferroelectric nitride materials.

### Brief Description of Related Technology

Due to intrinsic two-dimensional electron gas (2DEG) formation, III-nitride high electric mobility transistor (HEMT) devices tend to work under depletion mode. Depletion mode operation unfortunately consumes more power and causes safety problems. Thus, E-mode operation has been a long desired goal.

The ability to control and tune electrical polarization of semiconductor materials has been investigated to enable the design and development of various devices, including, for instance, microelectronic memory devices for neuromorphic computing and artificial intelligence, reconfigurable filters for mobile communications, micro/nanoelectromechanical systems, and tunable two-dimensional electron/hole gas (2DEG/2DHG) heterojunctions. Wurtzite III-nitride semiconductors, e.g., AlN, GaN, InN, and their alloys, possess a strong polarization effect along the c-axis, including spontaneous and piezoelectric polarization. The polarization direction of conventional III-nitrides, however, cannot be electrically switched without causing dielectric breakdown.

Ferroelectric gate stacks have been used to amplify the gate voltage controllability in connection with negative-capacitance field effect transistors (NC-FETs). In those applications, precise control of the gate stack structure is useful. The integration of different ferroelectric materials, including LNO, PZT, and In₂Se₃, with the 2DEG in an AlGaN/GaN heterostructure has been attempted.

### SUMMARY OF THE DISCLOSURE

In accordance with one aspect of the disclosure, a transistor device includes a substrate and a heterostructure supported by the substrate. The heterostructure includes a buffer layer supported by the substrate, a channel layer supported by the buffer layer, a barrier layer supported by the channel layer, and a gate dielectric layer supported by the barrier layer, the gate dielectric layer including a ferroelectric nitride alloy, the ferroelectric nitride alloy including a Group IIIB element.

In accordance with another aspect of the disclosure, a method of fabricating a transistor device includes providing a buffer layer supported by a substrate, growing epitaxially a channel layer supported by the buffer layer, growing epitaxially a barrier layer supported by the channel layer, and growing a gate dielectric layer supported by the barrier layer, the gate dielectric layer including a ferroelectric III-nitride alloy, the ferroelectric III-nitride alloy including a Group IIIB element.

In connection with any one of the aforementioned aspects, the devices and/or methods described herein may alternatively or additionally include or involve any combination of one or more of the following aspects or features. The ferroelectric nitride alloy has a switchable polarization in an out-of-plane direction. The barrier layer is configured to act as a dielectric layer such that the transistor device has a bi-layer gate dielectric structure. The barrier layer includes a III-nitride alloy. The barrier layer and the channel layer have different bandgaps. The gate dielectric layer is monocrystalline. The gate dielectric layer has a wurtzite structure. The buffer layer includes a III-nitride semiconductor material. The channel layer includes a III-nitride semiconductor material. The barrier layer includes a III-nitride semiconductor material. The gate dielectric layer includes ScAlN. The gate dielectric layer has a scandium content that falls in a range from about 0.05 to about 0.5. The buffer layer is in contact with the channel layer. The channel layer is in contact with the barrier layer. The gate dielectric layer is in contact with the barrier layer. The barrier layer and the channel layer define an interface such that a channel is formed in the channel layer. The III-nitride alloy is configured such that metal is not present at a surface of the barrier layer in contact with the gate dielectric layer. The heterostructure further includes a charge storage layer disposed between the barrier layer and the gate dielectric layer. The charge storage layer includes a single-digit number of monolayers. The charge storage layer includes ScN. Growing the channel layer and growing the barrier layer are implemented in a continuous growth procedure. Growing the barrier layer includes, after the barrier layer has been formed, interrupting epitaxial growth, and annealing the barrier layer at a temperature of a growth chamber such that metal at a surface of the barrier layer is evaporated. The method further includes forming a charge storage layer after growing the barrier layer and before growing the gate dielectric layer, the charge storage layer including a single-digit number of monolayers Growing the gate dielectric layer includes controlling a nitrogen flow such that a V/III flux ratio is greater than 1. The method further includes depositing a metal layer for source/drain contacts, and implementing an anneal procedure to establish ohmic contacts between the metal layer and the channel layer. Growing the gate dielectric layer includes annealing a wurtzite structure of the gate dielectric layer at a temperature higher than a temperature at which the wurtzite structure is grown. Growing the gate dielectric layer includes implementing a non-sputtered, epitaxial growth procedure under nitrogen-rich conditions. The gate dielectric layer is grown at a growth temperature that falls in a range from about 650 degrees Celsius or less. The channel layer, the barrier layer, and the gate dielectric layer are grown without removal from a reaction chamber.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) a schematic view of a transistor device having an epitaxial ScAlN/AlGaN/GaN ferroelectric HEMT device structure in accordance with one example, (b) a method of fabricating the HEMT device structure in accordance with one example, (c) a HAADF-STEM image of an example device captured from the gate stack region, (d) corresponding EDS mapping showing the element distribution in the example device, and (e) a high magnified HAADF-STEM image showing the atomic stacking at the heterostructure interface of the example device.

FIG. 2 depicts graphical plots of (a) J-V and (b) P-V loops measured from an example capacitor structure, in which non-switching current contribution has been subtracted, and (c) PUND measurement results for the capacitor structure.

FIG. 3 depicts graphical plots of (a) log-scale transfer characteristics for example epitaxial ferroelectric HEMT measured with different drain voltages, in which dashed curves are corresponding gate currents, and (b) linear-scale transfer curves of the characteristics and corresponding transconductances, in which the curves have been scaled to better show trends.

FIG. 4 depicts graphical plots of (a) transfer characteristics with different gate voltage scanning ranges in accordance with one example, showing the Vth tuning due to the ferroelectric switching of the barrier stacks, and (b) output characteristics of an example device after different poling voltages.

FIG. 5 depicts graphical plots of (a) transfer curves with different Vg steps in accordance with one example, and (b) calculated subthreshold swing according to the transfer curves, showing the steep-slope operation in accordance with one example.

FIG. 6 is a flow diagram of a method of fabricating a transistor device having a ferroelectric gate dielectric layer in accordance with one example.

FIG. 7 depicts (a) a schematic view of a transistor device having a ferroelectric gate dielectric layer in accordance with one example, and (b) a graphical plot of I-V curves showing a shift in threshold voltage (Vₜₕ) with increasing gate preset voltage (E-mode operation is achieved after presetting the gate voltage to 12 V).

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Transistor devices having a ferroelectric gate dielectric layer are described. The ferroelectric gate dielectric layer is disposed in a gate stack or other heterostructure of the transistor device in which a channel (e.g., a two-dimensional electron gas (2DEG) channel) is formed. The transistor devices may thus be configured as high electron mobility transistor (HEMT) devices. In some cases, the layers of the heterostructure are composed of, or otherwise include, III-nitride materials. Methods of fabricating such transistor devices including epitaxial growth of the layers of the heterostructure are also described. The fully epitaxial growth (e.g., by molecular beam epitaxy, MBE) allows high-quality ferroelectric-dielectric gate stacks for steep-slope III-nitride field effect transistors to be realized.

As described below, the disclosed transistor devices may be configured as ferroelectric transistors based on fully epitaxial ScAlN/AlGaN/GaN heterostructures. Atomically sharp interfaces confirmed the high quality of the heterostructures. Trapping-dominated clockwise and ferroelectric charge coupling dominated counterclockwise hysteretic loops were observed in the measured transfer characteristics. The threshold voltage tuning range was found to be highly dependent on the measurement condition, indicating that the pinch-off of the channel is coupled with ferroelectric switching. This coupling amplifies the controllability of the gate voltage and results in subthreshold swing of less than 60 mV/dec when tuning the gate voltage from positive to negative. Those results reveal the unique ferroelectric charge coupling in the epitaxial ferroelectric/2DEG heterostructures, thereby enabling the realization of ferroelectric enhanced transistor devices.

The integration of a ferroelectric gate dielectric layer and other semiconductor device layers may be useful in connection with a wide variety of device designs and applications. For instance, the integration of ferroelectrics with high electric mobility transistors (HEMTs) may be used to fabricate nitride semiconductor based memory devices, E-mode HEMT devices, and reconfigurable HEMT devices for functional and multi-discipline electronics.

The ferroelectric gate dielectric layer may be used to provide reconfigurable devices, including devices that are reconfigurable during operation. The reconfigurability may be useful in various ways, including, for instance, reducing power consumption, decreasing cost and chip space, and reducing chip complexity. To these and other ends, the reconfigurable devices may be programmed to work under different modes.

In some cases, the heterostructures of the disclosed devices include one or more nitride layers, such as III-nitride semiconductor layers. The nitride layers provide excellent radiation resistance and high-temperature stability, which may be useful in connection with various devices and application, including, for instance, memory applications in which data is stored in harsh environments.

The ferroelectric gate dielectric layer may be used to provide ferroelectric coupling and/or a ferroelectric charge trap gate stack, which may be used to tune the threshold voltage (Vₜₕ) of HEMT devices. For example, in ferroelectric coupling, a positive Vₜₕ shift is established with the help of a negative gate bias, which poles the polarization of the ferroelectric layer against that of a barrier layer (e.g., an AlGaN layer), and compensates the 2DEG in the channel. In an example charge trap scenario, a positive voltage is used to inject electrons to the gate-stack and electrons are then trapped there causing a positive shift of the threshold voltage. For reconfigurable and memory applications, ferroelectric charge coupling may be expected due to the instability of traps. Therefore, the threshold voltage tuning mechanisms in example epitaxial heterostructures (e.g., a ScAlN/AlGaN/GaN heterostructure) are addressed.

The ferroelectric gate dielectric layer of the heterostructures of the disclosed devices may be composed of, or otherwise include, a Sc-alloyed III-nitride material. Sc-alloyed III-nitride materials, such as ScAlN, have the same wurtzite structure as conventional III-nitride materials, and possess giant ferroelectric polarization and a large coercive field. The giant polarization provides more design room for ferroelectric charge coupling, while the large coercive field offers good depolarization resistance. The use of fully epitaxial growth procedures to form the ferroelectric layer allows the ferroelectric layer to be grown on top of III-nitride heterostructures. The resulting direct integration is useful for a number of reasons, including, for instance, less defects, higher stability, and better tunability.

In one example, ferroelectric HEMT devices were fabricated based on an epitaxial ScAlN/AlGaN/GaN heterostructure grown by MBE. The ScAlN layer of the heterostructure had a thickness of about 27 nm with a Sc content of about 30% Sc. The AlGaN layer of the heterostructure had a thickness of about 10 nm and an Al content of about 30%. The thicknesses and/or compositions may vary in other examples. As described below, clear hysteresis and large threshold voltage tuning range of about 3.8 V were achieved, with an ON/OFF ratio greater than 10⁷. The device exhibited multiple, distinct operation modes with different poling sequences. A voltage amplification effect due to ferroelectric switching was also observed, leading to subthreshold swing less than 60 mV/dec. The example and other devices described herein may be useful in nonvolatile and reconfigurable RF and power electronics applications, as well as memory devices and steep-slope transistors.

Although described in connection with examples of epitaxially grown ScₓAl₁₋ₓN layers, the disclosed methods and devices may be applied to a wide variety of nitride alloys (e.g., tantalum nitride (Ta₃N₅), ZnSi₂N, and III-nitride alloys). The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N layers, ScₓGa₁₋ₓN layers, or ScₓIn₁₋ₓN layers. The configuration, construction, fabrication, and other characteristics of the heterostructures may also vary from the examples described. For instance, the heterostructures may include additional or alternative epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although described in connection with examples having III-nitride-based layers, the disclosed methods and devices are not limited to heterostructures including III-nitride semiconductor layers as buffer, channel, barrier, or other layers or components of the heterostructure or device. Other semiconductor materials may be used, including, for instance, GaAs, InP, and alloys thereof. Still other types of materials may alternatively or additionally be used in the heterostructures, including, for instance, two-dimensional transition metal dichalcogenides, oxide materials (e.g., gallium oxide or gallium oxide-based materials), diamond, silicon carbide, and silicon.

Although some aspects of the disclosed methods are described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

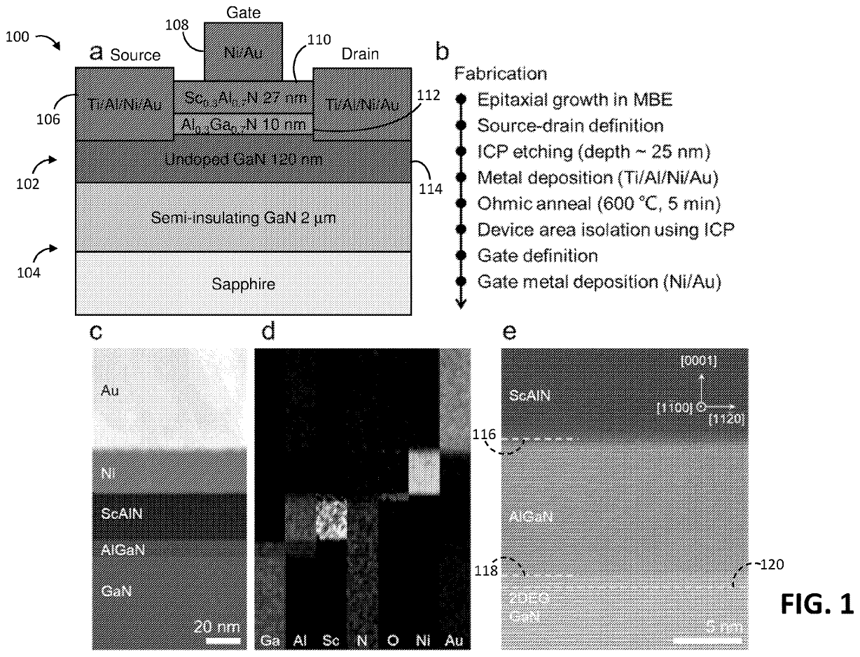

FIG. 1, part (a), depicts a schematic of a HEMT device 100 having a ScAlN/AlGaN/GaN ferroelectric heterostructure 102 in accordance with one example. In this example, the entire heterostructure 102 was epitaxially grown in a Veeco GENxplor MBE system on a commercial semi-insulating GaN/sapphire template 104. The epi-layers of the heterostructure 102 were undoped GaN having a thickness of about 120 nm, Al_{0.3}Ga_{0.7}N having a thickness of about 10 nm, and Sc_{0.3}Al_{0.7}N having a thickness of about 27 nm, with a channel carrier concentration and mobility of 8.2×10¹² cm⁻² and 1025 cm/(V·s), respectively.

FIG. 1, part (b), shows the steps of the device fabrication method used to fabricate the example device 100. In this case, photoresist was placed and patterned for source-drain contacts 106, following which a slight etching of about 25 nm by inductively coupled plasma (ICP). Then, a Ti/Al/Ni/Au metal stack was deposited, lifted-off, and annealed at 600° C. for 5 min in N₂ ambient, to form the source-drain contacts 106. A deep ICP etch (e.g., about 220 nm) is then implemented for mesa isolation and definition of the device area. The fabrication also includes a gate deposition (e.g., Ni/Au deposition) and lift-off to form a gate contact 108. In the examples characterized herein, the gate length and width are 5 μm and 10 μm, respectively, and the source-drain distance is about 20 μm. These and other device dimensions may vary in other cases.

Parts (c)-(e) of FIG. 1 depict the high resolution TEM images of the heterostructure 102. FIG. 1, part (c), illustrates the HAADF-STEM image captured from the gate stack region, showing abrupt, sharp, and clean interfaces between a ScAlN gate dielectric layer 110, an AlGaN barrier layer 112, and an undoped GaN layer 114. The corresponding energy dispersive spectroscopy (EDS) maps for Ga, Al, Sc, N, O, Ni, and Au elements are presented in FIG. 1, part (d), confirming the chemical composition of each layer.

In this example, a thin native oxide layer is present at the ScAlN top surface, which is mainly due to the large oxygen affinity for both Sc and Al elements. This layer will not affect the device performance except for acting as an additional thin dielectric layer. In other cases, an oxide layer is not present.

To confirm the epitaxial relationship, a high magnified HAADF-STEM image of the ScAlN/AlGaN/GaN stack region was captured (FIG. 1, part (e)). The epitaxially grown ScAlN layer 110 inherited the wurtzite atomic stacking sequence from the AlGaN layer 112 and the GaN layer 114 exactly. Additionally, the entire heterostructure possesses an atomic sharp interface (labeled as dashed lines 116, 118 in FIG. 1, part (e)). The transition region between each of the layers 110, 112, 114 is only about 1-2 monolayers, benefiting from the atomic-scale thickness controllability of the MBE growth. The 2DEG formed in the GaN channel near the AlGaN barrier layer 112 is labeled as dashed line 120 in FIG. 1, part (e).

The ferroelectric characteristics of a ferroelectric-semiconductor test structure are now addressed. The test structure includes a metal layer, a 27 nm Sc_{0.3}Al_{0.7}N layer, and an n-GaN layer. The 27 nm Sc_{0.3}Al_{0.7}N layer was first grown on the n-GaN layer. In this case, the n-GaN layer is Si-doped with nₑ of about 1×10¹⁹ cm⁻³. The test structure includes a metal-ferroelectric-semiconductor arrangement to study the intrinsic ferroelectric properties of the ScAlN layer.

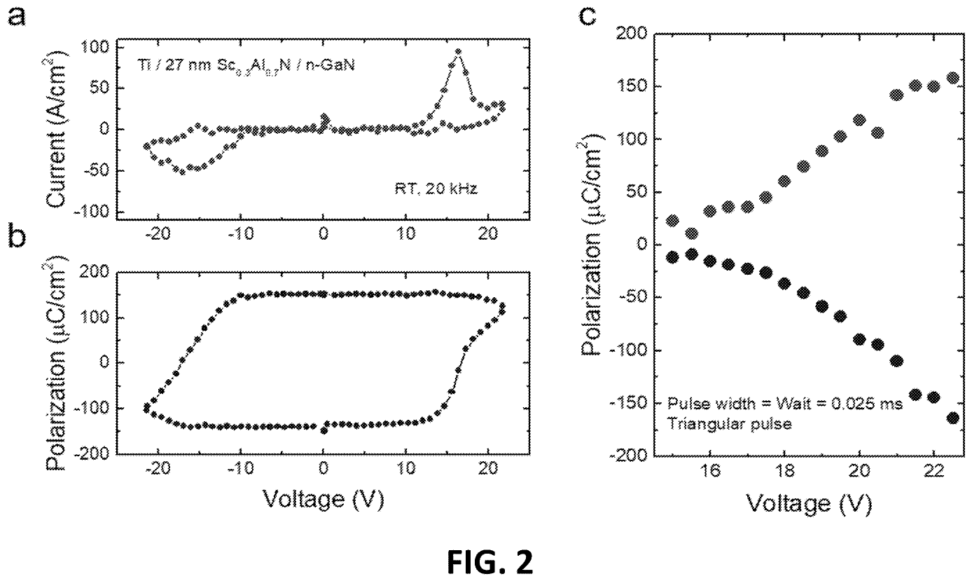

Parts (a) and (b) of FIG. 2 show the current-voltage (J-V) and polarization-voltage (P-V) characteristics of the test structure measured using triangular shape waveforms after subtracting the non-switching currents. FIG. 2, part (c), further displays the positive-up-negative-down (PUND) measurement results, demonstrating a remnant polarization of about 150 μC/cm². This giant switchable polarization is characteristic of emergent nitride ferroelectrics and may be useful, for instance, in significantly boosting polarization engineering in nitride-based heterostructures and devices.

The hysteretic transfer characteristics of an example HEMT device are now addressed.

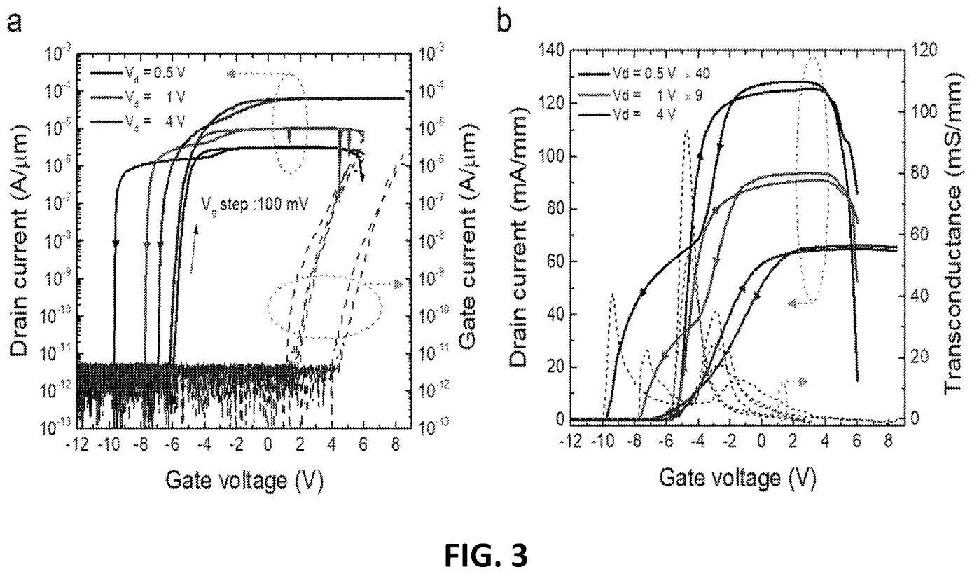

FIG. 3 shows the measured transfer characteristics of a HEMT device having a ScAlN/AlGaN/GaN-based heterostructure in accordance with one example. Both forward sweep (gate voltage, V_{g}, from negative to positive) and backward sweep (V_{g} from positive to negative) curves are captured to show the hysteresis induced by ferroelectric switching. During the measurement, the drain voltage was varied to tune the electric field profiles in the channel. Overall, the transfer curves show clear and significant counterclockwise hysteresis, indicating the successful ferroelectric coupling of the ScAlN gate dielectric. However, a small clockwise hysteresis region, close to the forward threshold voltage (forward Vₜₕ), can be observed. It is understood that under large positive bias, electrons are injected to and trapped in the barrier layer, as evidenced by the drastic increase in gate current, causing a positive shift of the Vₜₕ when V_{g} is swept from positive to negative. When the channel starts to deplete, the electrons in the barrier layer are released, and the classic counterclockwise hysteresis associated with ferroelectric charge coupling reappears. Optimization of the growth conditions may reduce the effect of trapping and de-trapping processes. It is also noted that the Vₜₕ tuning range is highly dependent on the drain voltage (V_{d}) during measurements, with a maximum value of about 3.8 V when V_{d}=0.5 V, indicating that the depletion of the channel during backward scan starts from the drain side. Due to the high quality epitaxial gate stacks, the device shows gate leakage limited off-currents, yielding a maximum ON/OFF ratio of 3×10⁷. Linear scale transfer curves and corresponding transconductances are further plotted in FIG. 3, part (b). The successful tuning of the threshold voltage Vₜₕ and transconductances may be useful in reconfigurable radio-frequency (RF), memory, and other devices.

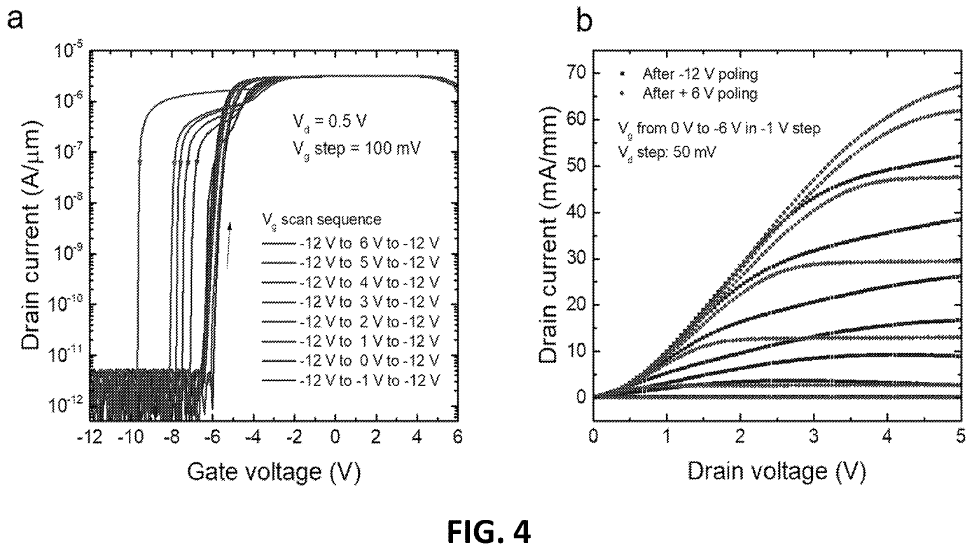

The example devices also exhibited gate-voltage dependent hysteresis and output characteristics. To investigate the ferroelectric charge coupling of the gate stack, transfer characteristics were measured with different positive gate voltage scan ranges. As shown in FIG. 4, part (a), the transfer curves show negligible hysteresis when the maximum positive gate voltage V_{g} is less than 2 V, indicating that no ferroelectric switching occurs at this stage. Further increasing the maximum positive gate voltage V_{g} gradually switches the polarity of the ferroelectric ScAlN layer to the same direction of the AlGaN layer and the GaN layer, which then enhances the 2DEG density in the channel and results in a negative shift of threshold voltage Vₜₕ in the backward scan, as shown in FIG. 4, part (a). Increasing gate voltage V_{g} to above 6 V increases the gate leakage current drastically.

FIG. 4, part (b), shows the output characteristics with gate voltage V_{g} scanning from 0 V to −6 V in −1 V steps after switching the polarity of the ScAlN layer to against (blue, or a darker shade of grey) or parallel (red, or a lighter shade of grey) to the polarity of the AlGaN/GaN layers. The nonvolatile feature of the ferroelectric polarization leads to two distinct programmable output curves, which may be useful in realizing non-volatile, reconfigurable ferroelectric HEMT and other devices.

Steep-slope subthreshold swing from ferroelectric gate voltage amplification. In ferroelectric HEMTs, the channel carrier concentration is co-determined by the polarization of the ferroelectric layer and the polarization discontinuity at the AlGaN/GaN interface. When the polarity of the ferroelectric layer is switched to be against that of the AlGaN and GaN layers, the ferroelectric polarization helps deplete the 2DEGs in the channel. When the polarity of the ferroelectric layer is switched to be parallel to that of the AlGaN and GaN layers, the polarization of the ferroelectric layer helps attract electrons and increase the 2DEG density in the channel. This enhanced modulation of the 2DEG from the ferroelectric polarization amplifies the controllability of the gate and leads to improved subthreshold performance.

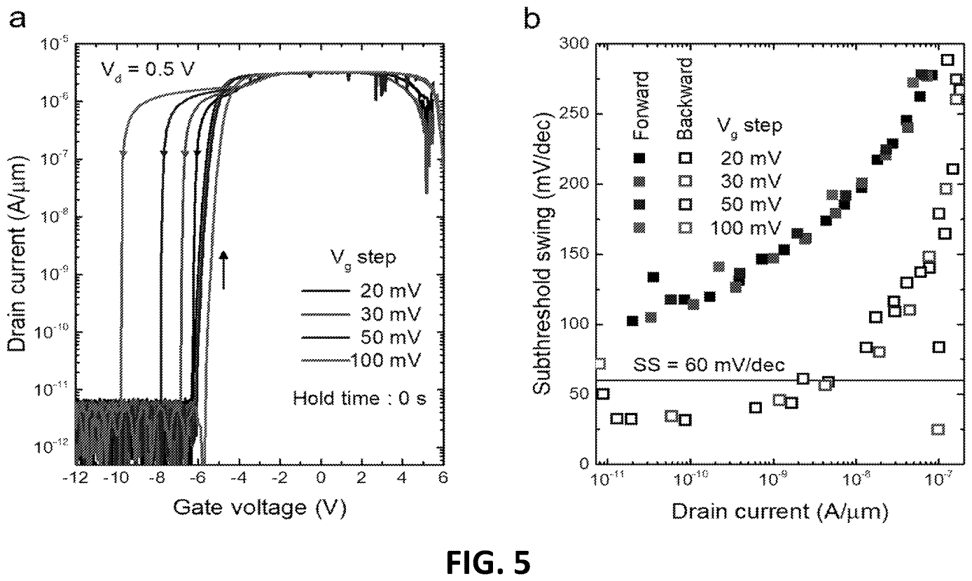

FIG. 5 shows the transfer characteristics and extracted subthreshold swing (SS) values with different V_{g} steps in connection with one example. SS values less than 250 mV/dec were obtained for a forward scan, which are smaller than most conventional HEMT structures and can be attributed to the large dielectric constant of the ScAlN layer. In contrast, the SS values obtained for a backward scan were even smaller, and a wide steep-slope window with SS values less than 60 mV/dec were observed, showing unambiguously the ferroelectric switching amplified gate voltage control. It is believed that during the backward scan, ferroelectric switching starts at around −6 V, which turns the polarity of the ScAlN layer against that of the AlGaN/GaN layers, leading to sharp depletion of the 2DEG.

During the measurement, the measurement time for each gate voltage V_{g} step was the same. In this case, for smaller gate voltage V_{g} steps, the total poling time is longer, resulting in a smaller hysteresis window, which is consistent with the results. The wide and stable steep-slope operation of the example epitaxial ferroelectric HEMT device may be useful in the realization of high performance transistor devices.

The Sc content, thickness, and other characteristics of the wurtzite-phase ScAlN layers of the disclosed devices and methods may from the examples described herein. For instance, the Sc content, x, may vary from about 0.05 to about 0.5 in some cases. The Sc content may fall outside this range in other cases.

The disclosed devices and methods may include one or more elements, aspects, or other features described in International Application No. PCT/US2022/028365, filed May 9, 2022, published as WO 2023/022768, and entitled “Epitaxial Nitride Ferroelectronics”, the entire disclosure of which is hereby incorporated by reference.

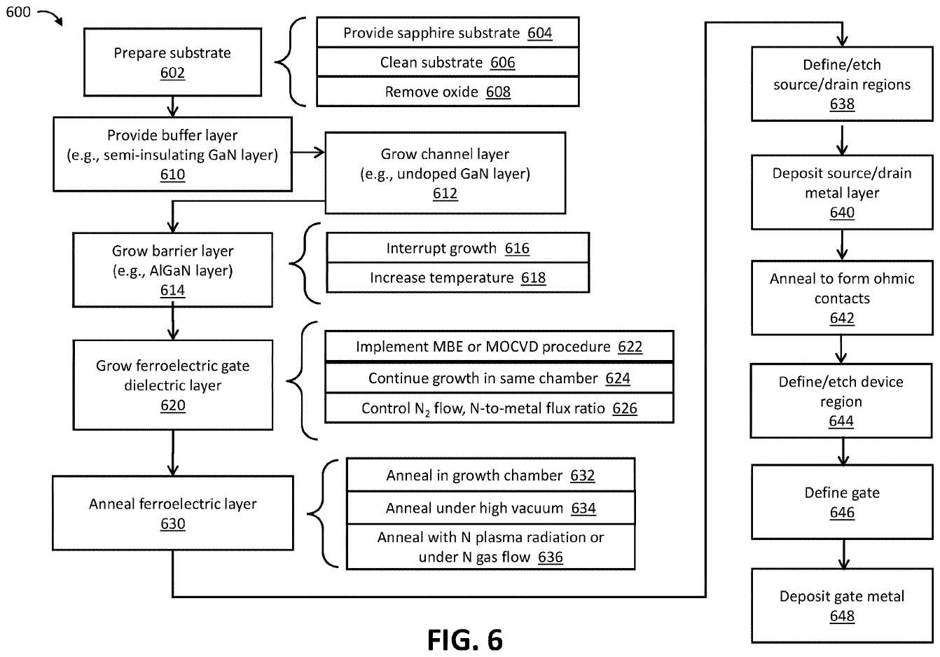

FIG. 6 depicts a method 600 of fabricating a transistor device having a heterostructure with a ferroelectric gate dielectric layer in accordance with one example. The method 600 may be used to fabricate the example devices described herein and/or other devices.

The method 600 may begin with an act 602 in which a substrate is prepared and/or otherwise provided. In some cases, the act 602 includes providing a sapphire substrate in an act 604. Alternative or additional materials may be used, including, for instance, silicon, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. Additional or alternative processing may be implemented in other cases, including, for instance, doping or deposition procedures. The substrate thus may or may not have a uniform composition. The substrate may be a uniform or composite structure.

In an act 610, one or more buffer layers are provided. Each buffer layer is supported by the substrate. In some cases, the layer(s) are provided with the substrate. The act 610 may thus be implemented before (e.g., in preparation for) implementing an epitaxial growth procedure in which a number of epitaxial layers of a heterostructure are formed. In other cases, the buffer layer(s) are formed (e.g., grown or deposited) on the substrate. The layer(s) may or may not be in contact with the substrate. The buffer layer(s) may or may not act as a growth template for one or more layers of the heterostructure.

In some cases, the layer(s) are composed of, or otherwise include, a semiconductor material. For example, a III-nitride layer, such as a semi-insulating GaN layer, may be grown or otherwise formed on the substrate. Other compound or other semiconductor materials may be used, including, for instance, AlGaN and non-III-nitride materials, as described above. The heterostructure may thus be formed on the semiconductor layer.

In some cases, the act 610 may include growing the semiconductor layer in an epitaxial growth chamber in which the epitaxial growth procedure for the heterostructure is implemented. As a result, the substrate may remain within, e.g., is not removed from, the epitaxial growth chamber between forming the semiconductor layer and implementing the epitaxial growth procedure for growing the wurtzite structure.

In an act 612, a channel layer of the heterostructure is grown. In some cases, the channel layer is composed of, or otherwise includes, undoped GaN. Additional or alternative materials may be used, including other III-nitride materials and non-III-nitride materials. The channel layer may be grown via implementation of an epitaxial growth procedure, such as MBE, used to grow multiple layers of the heterostructure.

In an act 614, a barrier layer of the heterostructure is grown. In some cases, the barrier layer is composed of, or otherwise includes, AlGaN. Additional or alternative materials may be used, including other III-nitride materials and non-III-nitride materials. The epitaxial growth procedure used to grow the channel layer may be continued (e.g., a continuous growth procedure) to grow the barrier layer. Thus, the substrate may remain in the same growth chamber during the acts 612 and 614.

After the growth of the barrier layer, the act 614 may include one or more acts in preparation for growth of the ferroelectric gate dielectric layer. In the example of FIG. 6, growth is interrupted in an act 616. The growth interruption may include closing one or more shutters of the growth chamber. The temperature of the growth chamber may then be increased in an act 618 to anneal the barrier layer a level at which metal on the surface of the barrier layer is evaporated. Such removal of metal atoms along the surface may help improve the quality of the ferroelectric gate dielectric layer.

In an act 620, the ferroelectric gate dielectric layer is grown. As described herein, the ferroelectric gate dielectric layer may be composed of, or otherwise include, an alloy of a III-nitride material. For instance, the III-nitride material may be AlN. Additional or alternative III-nitride materials may be used, including, for instance, gallium nitride (GaN), indium nitride (InN), and their alloys. As also described herein, an epitaxial growth procedure is implemented and configured to incorporate scandium and/or another group IIIB element into the alloy of the III-nitride material. The alloy may thus be ScₓAl₁₋ₓN, for example. In some cases, the act 620 includes an act 622 in which an MBE procedure is implemented. In other cases, an MOCVD or other non-sputtered epitaxial growth procedure is implemented.

The act 620 may constitute a continuation, or part of a sequence, of the growth procedures used to form other layers of the heterostructure. The growth procedures may be implemented in a common, or same, growth chamber without removal therefrom. The act 620 may thus include an act 624 in which epitaxial growth is continued in the same chamber. Sequential layers of the heterostructure may thus be grown without exposure to the ambient. The quality of the interface between the layers may accordingly be improved.

The growth temperature may be at a level such that the ferroelectric dielectric layer has a wurtzite structure that exhibits a breakdown field strength greater than a ferroelectric coercive field strength of the wurtzite structure. The gate dielectric layer may thus exhibit ferroelectric switching and other behavior.

In some cases, the growth temperature is at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a ScₓAl₁₋ₓN alloy may be epitaxially grown at a growth temperature of about 650 degrees Celsius or about 750 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius, about 750 degrees Celsius, or lower than about 650 or 750 degrees Celsius, would result in structures of such poor quality so as to be useless. In contrast, the epitaxially grown ScₓAl₁₋ₓN layer grown at such low or even lower temperatures is unexpectedly monocrystalline and of high quality.

The low growth temperature may be applied in cases in which the nitrogen-to-metal (V/III) flux ratio is slightly or moderately nitrogen-rich. For example, the V/III flux ratio may be in a range between about 1-to-1 to about 2-to-1. In other cases in which the nitrogen-to-metal flux ratio is highly unbalanced, i.e., an extreme N-rich regime, as described herein, the growth temperature may be higher. For instance, the V/III flux ratio may be higher than about 2-to-1. In such highly unbalanced cases, the growth temperature may be at a level and/or otherwise fall in a range that includes temperatures at which the III-nitride material (i.e., without scandium) would typically be grown.

The highly unbalanced, extremely N-rich conditions may be used in connection with formation of the wurtzite structure via sputter deposition. The aforementioned defects presented by past efforts to use sputtering to achieve a ferroelectric layers, such as ScₓAl₁₋ₓ N layers are avoided as a result of the use of the highly unbalanced, extremely N-rich conditions.

In slightly to moderately unbalanced, N-rich cases, growth of the ScₓAl₁₋ₓN layer at the conventional AlN growth temperature (and other temperatures above the upper bound) unexpectedly results in the formation of dislocations and/or other leakage paths in the ScₓAl₁₋ₓ N layer. With the leakage paths, the ScₓAl₁₋ₓN layer has a breakdown field strength level too low (e.g., below the ferroelectric coercive field strength level). The layer accordingly does not exhibit ferroelectric behavior.

In some cases (e.g., slightly to moderately unbalanced, N-rich cases), the growth temperature may be about 650 degrees Celsius or less or about 750 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range in slightly to moderately unbalanced, N-rich cases may vary in accordance with the alloy and/or the epitaxial growth technique. For instance, in other slightly to moderately unbalanced, N-rich cases, the upper bound on the growth temperature may be higher, such as about 680 degrees Celsius, or about 690 degrees Celsius. In still other slightly to moderately unbalanced, N-rich cases, the upper bound may be lower, including, for instance, about 600 degrees Celsius or about 620 degrees Celsius.

The growth temperature may vary in cases in which other process parameters differ from those described above. For instance, a higher growth temperature may be used in cases in which the nitrogen-metal flux ratio is highly or extremely unbalanced as described below. The nitrogen-to-metal flux ratio may be set in an act 626 in which the nitrogen flow is controlled. In some cases, the unbalanced flux ratio may be set to a highly or extremely nitrogen (N)-rich condition, such as a N-to-metal flux ratio of 2-to-1 or higher. In such cases, the growth temperature may fall in a range corresponding with those temperatures to grow other III-nitride layer(s) of the device, e.g., in the acts 612, 614. For example, growth temperatures about 1000 degrees Celsius may be used. In other highly or extremely N-rich growth condition examples, lower growth temperatures, e.g., those falling in a range from about 600 degrees Celsius to about 1000 degrees Celsius as in the examples described above, may be used.

Control of the flux ratio between metal and nitrogen sources may be useful for improving the material quality of nitride semiconductors, including, for instance, ScₓAl₁₋ₓN. In conventional III-nitrides, slightly metal-rich growth conditions are often used to improve the surface morphology, interface controllability, and crystal quality during the MBE growth processes. Based on the phase diagram of Sc—Al—N, N-rich growth conditions, however, are more favorable for the growth of ScAlN to avoid Sc—Al intermetallic and SC₃AlN perovskite phase formation. Whether the film is grown in N-poor or N-rich conditions may result in different formation energy levels for defects, such as cation vacancies (V_{cation}) and nitrogen vacancies (V_{N}), which may further affect the electrical properties, including, for instance, leakage current and breakdown strength.

Such highly N-rich growth conditions may be employed in connection with MBE, MOCVD and other epitaxial growth processes. The highly N-rich growth conditions may also be utilized in connection with films formed via sputter deposition.

At each level within the above-described ranges of suitable growth temperatures, the resulting wurtzite structure is monocrystalline. The resulting wurtzite structure is monocrystalline to a degree not realizable via, for instance, sputtering-based procedures for forming ScₓAl₁₋ₓN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

The ferroelectric layer may then be annealed in an act 630. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III—N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScₓAl₁₋ₓN may be performed in-situ in the same growth chamber (e.g., the same MBE chamber) in an act 632. In other cases, the annealing is performed ex-situ in a chamber directed to annealing procedures.

The annealing process may be implemented under high vacuum in an act 634 (e.g., in-situ in the growth chamber). In other cases, the annealing may be implemented either with nitrogen plasma radiation or under nitrogen gas flow in an act 636.

The above-described annealing procedure may be implemented in connection with films grown under any of the above-described growth conditions. For instance, the annealing procedure may be implemented after growth under slightly to moderately N-rich conditions at a growth temperature at or below about 650 degrees Celsius, or at or below about 750 degrees Celsius. The annealing procedure may also be implemented after growth under other unbalanced flux ratios (e.g., N-rich or extreme N-rich conditions) at growth temperatures above about 650 degrees Celsius or above about 750 degrees Celsius.

The method 600 may include an act 638 in which source and drain areas are defined and etched after growth of the wurtzite structure. The act 638 may include the implementation of a plasma etch procedure, but alternative or additional etch procedures may be used.

One or more metal layers may then be deposited in an act 640. A lift-off step may then be implemented to form source and drain regions in the areas defined in the act 638. The composition and other characteristics of the source and drain regions may vary.

The method 600 may include implementation of an anneal procedure in an act 642. The anneal procedure may be configured to form ohmic contacts between a metal layer of the source/drain regions and the channel layer.

The method 600 may then include a number of acts directed to further defining the device and device area. In the example of FIG. 6, a device region (e.g., a mesa) is defined and etched in an act 644. A gate region is defined in an act 646, and one or more metal layers are deposited in an act 648. A liftoff procedure may then be implemented to define the gate.

The method 600 may include one or more additional acts. For example, one or more acts may be directed to forming additional layers of the heterostructure of additional components of the device. For instance, one or more acts may be configured to form additional metal layers for interconnects and/or other connections. The nature of the regions or structures may vary in accordance with the nature of the device.

The order of the acts of the method 600 may differ from the example shown in FIG. 6. For example, one or more annealing acts may be implemented at a different point in the fabrication process.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScₓAl₁₋ₓN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

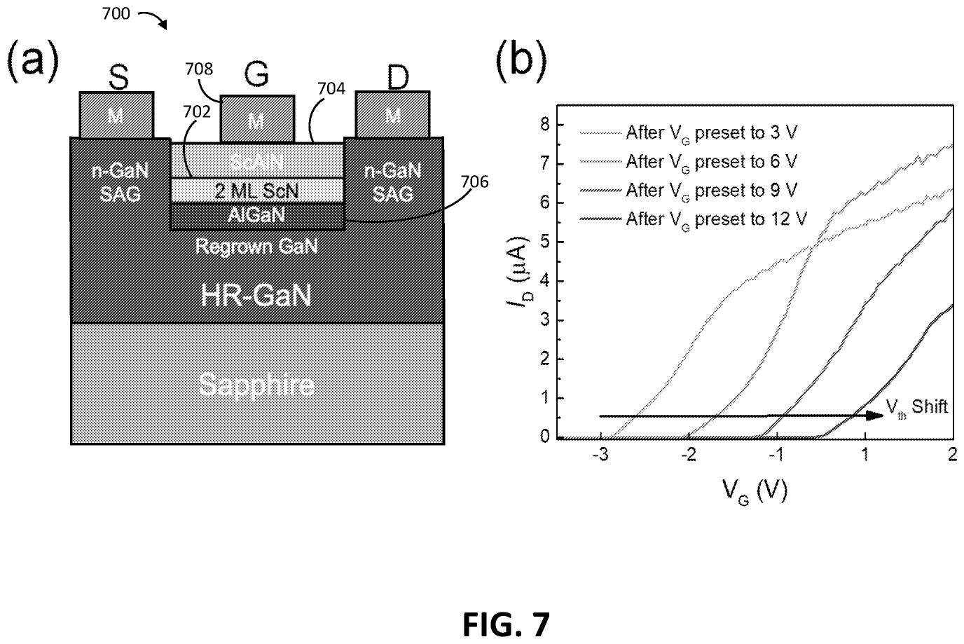

FIG. 7 depicts a ferroelectric HEMT device 700 in accordance with one example. The device 700 may have one or more layers, regions, components, or other elements in common with one or more of the above-described devices. In this case, the device 700 has a charge storage (or trapping) layer 702 disposed between a ferroelectric gate dielectric layer 704 and a barrier layer 706. The charge storage layer 702 may include a single monolayer of ScN. The ScN monolayer acts as a charge storage layer by capturing injected electrons from a gate electrode 708. The trapped electrons lead to a higher potential of the barrier layer 706, which gives rise to a right shift of the threshold voltage and enables enhanced-mode operation. This approach, e.g., using monolayer ScN as the charge trapping layer, serves as an alternative (or additional) way to stabilize or otherwise provide enhanced mode operation in Fe-HEMT devices (e.g., apart from the ferroelectric polarization).

The thickness of the charge storage layer 702 may vary. For instance, in some cases, a single-digit number of monolayers may be provided. In the example of FIG. 7, the charge storage layer 702 may have one or two monolayers.

The charge storage layer 702 is formed after the growth of the barrier layer 706 and before the growth of the ferroelectric gate dielectric layer 704. For instance, the charge storage layer 702 may be formed during the transition between the epitaxial growth of the ferroelectric gate dielectric layer 704 and the barrier layer 706. For example, in some cases, the charge storage layer 702 is formed during or at the end of the growth interruption act 616 (FIG. 6). For instance, the growth interruption act 616 may include a period of time after the closing of the Al and Ga shutters, in which the Sc shutter is opened. Alternatively or additionally, the formation of the charge storage layer 702 may be implemented before the growth interruption act 616.

The composition of the charge storage layer 702 may vary from the example of FIG. 7. For instance, other nitride semiconductor materials may be used. For example, the composition of the charge storage layer 702 may vary in accordance with the composition (e.g., Group IIIB element) of the gate dielectric layer 704.

As shown in FIG. 7, part (b), by gradually poling the gate voltage to the positive side, the threshold voltage gradually increases due to an increase in trapped electron densities when poling the gate to higher positive voltages. Using a negative gate voltage, the threshold voltage may further be programmed back to its initial state, which may be useful in connection with reconfigurable Fe-HEMT devices, e.g., by adding more design room.

Described above are examples of ferroelectric transistors based on fully epitaxial ScAlN/AlGaN/GaN heterostructures. The examples exhibited atomically sharp interfaces, confirming the high quality of the heterostructures. Ferroelectric charge coupling induced counterclockwise hysteretic loops were successfully demonstrated in the measured transfer characteristics. The threshold voltage tuning range was found to be highly dependent on the measurement condition, with a maximum tuning range of about 3.8 V, indicating the giant channel carrier modulation effect of ferroelectric switching. This modulation also helps amplify the controllability of the gate voltage and results in subthreshold swing less than 60 mV/dec when tuning the gate voltage from positive to negative. Those results reveal the fundamental ferroelectric charge coupling in the epitaxial ferroelectric/2DEG heterostructures and enable the fabrication of ferroelectric enhanced transistors.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A transistor device comprising:
a substrate; and
a heterostructure supported by the substrate;
wherein the heterostructure comprises:
a buffer layer supported by the substrate;
a channel layer supported by the buffer layer;
a barrier layer supported by the channel layer; and
a gate dielectric layer supported by the barrier layer, the gate dielectric layer comprising a ferroelectric nitride alloy, the ferroelectric nitride alloy comprising a Group IIIB element.

2. The transistor device of claim 1, wherein the ferroelectric nitride alloy has a switchable polarization in an out-of-plane direction.

3. The transistor device of claim 1, wherein the barrier layer is configured to act as a dielectric layer such that the transistor device has a bi-layer gate dielectric structure.

4. The transistor device of claim 1, wherein the barrier layer comprises a III-nitride alloy.

5. The transistor device of claim 1, wherein the barrier layer and the channel layer have different bandgaps.

6. The transistor device of claim 1, wherein the gate dielectric layer is monocrystalline.

7. The transistor device of claim 1, wherein the gate dielectric layer has a wurtzite structure.

8. The transistor device of claim 1, wherein the buffer layer comprises a III-nitride semiconductor material.

9. The transistor device of claim 1, wherein the channel layer comprises a III-nitride semiconductor material.

10. The transistor device of claim 1, wherein the barrier layer comprises a III-nitride semiconductor material.

11. The transistor device of claim 1, wherein the gate dielectric layer comprises ScAlN.

12. The transistor device of claim 1, wherein the gate dielectric layer has a scandium content that falls in a range from about 0.05 to about 0.5.

13. The transistor device of claim 1, wherein:
the buffer layer is in contact with the channel layer;
the channel layer is in contact with the barrier layer; and
the gate dielectric layer is in contact with the barrier layer.

14. The transistor device of claim 1, wherein the barrier layer and the channel layer define an interface such that a channel is formed in the channel layer.

15. The transistor device of claim 1, wherein the III-nitride alloy is configured such that metal is not present at a surface of the barrier layer in contact with the gate dielectric layer.

16. The transistor device of claim 1, wherein the heterostructure further comprises a charge storage layer disposed between the barrier layer and the gate dielectric layer.

17. The transistor device of claim 16, wherein the charge storage layer comprises a single-digit number of monolayers.

18. The transistor device of claim 16, wherein the charge storage layer comprises ScN.

19. A method of fabricating a transistor device, the method comprising:
providing a buffer layer supported by a substrate;
growing epitaxially a channel layer supported by the buffer layer;
growing epitaxially a barrier layer supported by the channel layer; and
growing a gate dielectric layer supported by the barrier layer, the gate dielectric layer comprising a ferroelectric III-nitride alloy, the ferroelectric III-nitride alloy comprising a Group IIIB element.

20. The method of claim 19, wherein growing the channel layer and growing the barrier layer are implemented in a continuous growth procedure.

21. The method of claim 19, wherein growing the barrier layer comprises, after the barrier layer has been formed:
interrupting epitaxial growth; and
annealing the barrier layer at a temperature of a growth chamber such that metal at a surface of the barrier layer is evaporated.

22. The method of claim 19, further comprising forming a charge storage layer after growing the barrier layer and before growing the gate dielectric layer, the charge storage layer comprising a single-digit number of monolayers.

23. The method of claim 19, wherein growing the gate dielectric layer comprises controlling a nitrogen flow such that a V/III flux ratio is greater than 1.

24. The method of claim 19, further comprising:
depositing a metal layer for source/drain contacts; and
implementing an anneal procedure to establish ohmic contacts between the metal layer and the channel layer.

25. The method of claim 19, wherein growing the gate dielectric layer comprises annealing a wurtzite structure of the gate dielectric layer at a temperature higher than a temperature at which the wurtzite structure is grown.

26. The method of claim 19, wherein growing the gate dielectric layer comprises implementing a non-sputtered, epitaxial growth procedure under nitrogen-rich conditions.

27. The method of claim 19, wherein the gate dielectric layer is grown at a growth temperature that falls in a range from about 650 degrees Celsius or less.

28. The method of claim 19, wherein the channel layer, the barrier layer, and the gate dielectric layer are grown without removal from a reaction chamber.
